(19) United States
(12) Patent Application Publication
(10) Pub. No.: US 2010/0155707 A1
(43) Pub. Date: Jun. 24, 2010

(54) ORGANIC FIELD-EFFECT TRANSISTORS

(76) Inventor: Thomas Anthopoulos, London (GB)

Correspondence Address: HAYNES AND BOONE, LLP;IP Section, 2323 Victory Avenue, Suite 700, Dallas, TX, 75219, US

(21) Appl. No.: 12/594,035

(22) PCT Filed: Apr. 1, 2008
(86) PCT No.: PCT/GB08/01188

§ 371 Date: Feb. 1, 2010

(30) Foreign Application Priority Data
Apr. 5, 2007 (GB) 0706756.4

(51) Int. Cl. H01L 51/30; H01L 51/40

(52) U.S. Cl. 257/40; 438/99; 977/735; 257/E51.027

(57) ABSTRACT

An organic field-effect transistor comprising: a source region; a drain region; one or more organic semiconductor layers disposed between the source and drain regions; a gate region; and a dielectric region disposed between the organic semiconductor layer(s) and the gate region; wherein the composition of the organic semiconductor layer(s) is such as to transport both electrons and holes, with the mobility of the holes being substantially equal to the mobility of the electrons such that the transistor substantially exhibits ambipolarity in its transfer characteristics. The organic field-effect transistor is preferably a light-sensing organic field-effect transistor. Numerous modifications to the composition and structure of organic field-effect transistors are also disclosed, as are examples of electro-optical switches, electro-optical logic circuits and image sensing arrays.

This invention relates to organic field-effect transistors (OFETs). In particular, but not exclusively, the invention relates to the fabrication of discrete light sensing OFETs and their use in sensing arrays and electro-optical circuits for a number of technological applications.

### BACKGROUND TO THE INVENTION

Traditionally, organic field-effect transistors (OFETs) have been used as current modulating, or switching, devices in logic circuits and as pixel switches in active matrix displays.[1] Recently, however, OFETs with additional functionalities, e.g. bifunctional OFETs, have also been demonstrated, with the most notable examples being light-emitting OFETs (LE-OFETs)[2] and light-sensing OFETs (LS-OFETs)[3]. These latter two demonstrations are very interesting since, in principle, design and fabrication of electro-optical circuits can be envisioned in which the electrical and optical functionalities of the bifunctional OFETs are combined.

LS-OFETs have been demonstrated by several research groups around the world. Most of these devices rely on the photoconductive effect of the electroactive layer employed (i.e. the organic semiconductor). However, because they rely on photoconductivity effects, such devices exhibit a transition time of the order of seconds to relax from an activated excited state to an inactivated relaxed state. It will be appreciated that such a transition time is far too slow for most practical purposes, in particular for the detection of information transmitted using pulsed optical signals or for imaging moving people and automobiles.

Other approaches towards LS-OFETs demonstrated so far include devices based on ambipolar organic blends and p-n type heterostructures.

LS-OFETs using ambipolar organic blends have been demonstrated by Marjanović et al.[3] Ambipolar blends effectively combine p-type and n-type materials, i.e. are capable of transporting both electrons and holes, and are used with a view to obtaining a high photogeneration capability. However, the LS-OFETs demonstrated by Marjanović et al., although based on ambipolar organic blends, do not in fact exhibit ambipolarity in their transfer characteristics. This is illustrated in FIGS. 2 and 3 of Marjanović[3], in which the transfer characteristics under a positive gate voltage are radically different from the transfer characteristics under a negative gate voltage. In these figures, the channel current I_{D} increases rapidly with gate voltage magnitude when the gate voltage is positive, but shows little or no increase with gate voltage magnitude when the gate voltage is negative.

The operation of p-n type heterostructures relies on the photovoltaic effect rather than the semiconductor's photoconductivity, hence leading to faster device response. This is because, with the photovoltaic effect, no trapped charges are released over time. However, apart from discrete LS-OFET demonstrations, no real applications of such devices have neither been demonstrated nor envisioned.

### SUMMARY OF THE INVENTION

According to a first aspect of the present invention there is provided an organic field-effect transistor as defined in Claim 1 of the appended claims. Thus there is provided an organic field-effect transistor comprising: a source region; a drain region; one or more organic semiconductor layers disposed between the source and drain regions; a gate region; and a dielectric region disposed between the organic semiconductor layer(s) and the gate region; wherein the composition of the organic semiconductor layer(s) is such as to transport both electrons and holes, with the mobility of the holes being substantially equal to the mobility of the electrons such that the transistor substantially exhibits ambipolarity in its transfer characteristics.

The term “organic”, as used herein, should be interpreted broadly to encompass organometallic materials and other organic derivatives, as well as purely organic materials. Example materials include small molecules, co-polymers, polymers, oligomers and dendrimers.

By virtue of the transistor exhibiting ambipolarity in its transfer characteristics, it enables rapid reversible switching that has not been demonstrated by prior art organic field-effect transistors. Advantageously, switching speeds of the order of kHz may be achieved using an embodiment of the invention, and those skilled in the art will appreciate that this technology may be developed to realise even faster switching speeds in the future.

Preferable, optional, features are defined in the dependent claims.

Thus, preferably the said organic semiconductor layer(s) comprises a single layer. Particularly preferably the organic semiconductor layer is a blend of n-type and p-type semiconductor materials. In a presently-preferred embodiment the n-type transporter comprises [6,6]-phenyl-C₆₁-butyric acid methyl ester ([60]PCBM) and the p-type transporter comprises poly[2-methoxy-5-(3′,7′-dimethyloctyloxy)]-p-phenylene vinylene (OC₁C₁₀-PPV). The [60]PCBM:OC₁C₁₀-PPV ratio is preferably in the range of approximately 8:1 to 20:1 by weight, and is particularly preferably in the range of approximately 15:1 to 20:1 by weight. Such compositions advantageously enable approximately equal mobility of electrons and holes through the ambipolar layer.

Preferably the channel length from the source region to the drain region is in the range of approximately 0.5 μm to 50 μm. Particularly preferably the channel length is in the range of approximately 1 μm to 2 μm. This advantageously results in a significant increase in the switching speed of the transistor.

In one embodiment the single ambipolar organic semiconductor layer is adapted such that free carrier photogeneration and transport occurs within the semiconductor material. Such devices may have detection wavelengths in the near IR region, which makes them attractive for applications in optical telecom systems and near-IR image sensor arrays. The single ambipolar organic semiconductor layer may comprise dithiolene or squaraine or derivatives thereof.

According to a second aspect of the present invention there is provided an organic field-effect transistor comprising: a source region; a drain region; one or more organic semiconductor layers disposed between the source and drain regions; a gate region; and a dielectric region disposed between the organic semiconductor layer(s) and the gate region; wherein the channel length from the source region to the drain region is in the range of approximately 0.5 μm to 50 μm. This advantageously results in a significant increase in the switching speed of the transistor.

According to a third aspect of the present invention there is provided an organic field-effect transistor comprising: a source region; a drain region; first and second organic semiconductor layers disposed between the source and drain regions; a gate region; and a dielectric region disposed between the gate region and the first and second organic semiconductor layers; wherein the said first and second organic semiconductor layers comprise separate n-channel and p-channel layers.

Such a device provides the advantage that charge transport along the p- and n-channel layers may be optimised, and photogenerated carriers may be rapidly transferred to the corresponding collecting electrode. Thus a faster switching response may be obtained.

A third layer may be provided between the first and second organic semiconductor layers, the third layer being a high photogeneration efficiency layer. Such a device advantageously combines the high photogeneration efficiency of bulk-heterojunction systems with the optimised transport characteristics of p-n heterostructure transistors.

According to a fourth aspect of the present invention there is provided an organic field-effect transistor comprising: a source region; a drain region; an organic semiconductor layer disposed between the source and drain regions, the organic semiconductor layer being a unipolar transport layer; a photosensitizer layer disposed on the unipolar transport layer; a gate region; and a dielectric region disposed between the gate region and the organic semiconductor layers. Such a device may provide improved switching characteristics due to high unipolar carrier mobility.

With all the above-mentioned aspects of the invention, the transistor is preferably a light-sensing organic field-effect transistor.

Further aspects of the present invention provide methods of forming organic field-effect transistors.

A further aspect of the present invention provides an electro-optical switch comprising a light-sensing organic field-effect transistor. Highly advantageously, the electro-optical switch disclosed herein is capable of a switching speed of the order of kHz, which is significantly faster than light-sensing organic field-effect transistors disclosed in the prior art. Those skilled in the art will appreciate that this technology may be developed to achieve even faster switching speeds in the future.

A further aspect of the present invention provides an electro-optical circuit comprising one or more light-sensing organic field-effect transistor(s). This circuit may be a logic circuit, and may comprise one or more logic gates such as a NOT gate, an OR gate, an AND gate, a NAND gate, or any combination thereof. Such logic circuits may be used to process optical signals, or a combination of electrical and optical signals, and may provide an electrical output. Advantageously, such circuits may also be used to perform analogue signal operations as well as binary operations. Thus, light intensity and wavelength information may be captured and processed.

A further aspect of the present invention provides an image sensing array comprising a plurality of light-sensing organic field-effect transistors. Preferably the image sensing array comprises a plurality of pixels, wherein each pixel comprises a plurality of sub-pixels, and each sub-pixel comprises a wavelength-selective light-sensing organic field-effect transistor.

With all the aspects of the invention, preferable, optional, features are defined in the dependent claims.

Transistors, image sensing arrays, and other devices according to embodiments of the invention may advantageously be fabricated on flexible or curved substrates.

The present devices provide the advantages of inter alia better photovoltaic response from a single ambipolar layer in an LS-OFET; the ability to form an ambipolar layer from more than one constituent layer; and circuits for applications of such LS-OFET structures.

### BRIEF DESCRIPTION OF THE DRAWINGS

Embodiments of the invention will now be described, by way of example only, and with reference to the drawings in which:

FIG. 1 illustrates a conventional semiconductor field-effect transistor;

FIG. 2 illustrates a light sensing organic field-effect transistor (LS-OFET);

FIG. 3 illustrates the evolution of the inverse drain current I_{D} with time of an LS-OFET (lower trace) according to an embodiment of the invention, subjected to a pulsed LED, the upper trace showing the light pulse intensity as measured by a silicon photodiode;

FIG. 4 illustrates (a) transfer characteristics for an ambipolar LS-OFET based on a heterogeneous blend, according to an embodiment of the invention, with measurements performed under darkness and under constant illumination using an inorganic blue LED; and (b) values of I_{D} measured with the blue LED ON divided by values of I_{D} measured with the LED OFF;

FIG. 5 illustrates (a) transfer characteristics of an LS-OFET according to an embodiment of the invention, measured in darkness and under pulsed light illumination, at different intensities (inset: circuitry of the measurement set-up employed); and (b) evolution of drain current with time under pulsed excitation with light using a blue LED;

FIG. 6 illustrates a sequence of steps in the production of an LS-OFET according to an embodiment of the invention;

FIG. 7 illustrates various alternative LS-OFET structures, namely (a) a p-n type organic heterostructure based LS-OFET; (b) a multilayer light-sensing LS-OFET incorporating a free carrier photogeneration layer and optimised p- and n-type transport layers employing asymmetric S-D contacts; (c) a unipolar (n-type) LS-OFET utilising a photosensitizer layer; and (d) an LS-OFET based on a single layer ambipolar organic semiconductor;

FIG. 8 illustrates an electro-optical switch based on an LS-OFET (T1) and an OFET (T2);

FIG. 9 illustrates electro-optical logic circuits based on LS-OFETs and unipolar OFETs, namely (a) a NOT gate; (b) an OR gate; (c) two AND gates, one having one optical input (A_{IN}) and one electrical input (B_{IN}) (left hand side circuit), and the other having two optical inputs (right hand side circuit); and (d) two NAND gates, one having one optical input (A_{IN}) and one electrical input (B_{IN}) (left hand side circuit), and the other having two optical inputs (right hand side circuit);

FIG. 10 illustrates the operation of an experimental electro-optical inverter based on a LS-OFET (T2) and a unipolar OFET (T1);

FIG. 11 illustrates the operation of an experimental electro-optical OR gate employing two transistors, one LS-OFET (T1) and one ordinary unipolar OFET (T2);

FIG. 12 illustrates circuitry of a three-colour light sensing pixel based on three LS-OFETs, i.e. T1_{B}, T1_{G}, and T1_{R};

FIG. 13 illustrates a plan schematic cross-sectional view of a curved or flexible imaging device or sensing array; and

FIG. 14 illustrates a plan schematic cross-sectional view of an imaging sensor which curves through 360°, thus being circular in form.

The specific circuitry of the gates and pixels described herein are based on the CMOS layout. This however need not be the case, and circuits can be designed using different circuitry approaches such as N-MOS and P-MOS layouts, which will be familiar to those skilled in the art, or other alternatives known to those skilled in the art. Different approaches have different advantages and disadvantages, as those skilled in the art will appreciate.

### DETAILED DESCRIPTION OF PREFERRED EMBODIMENTS

The present embodiments represent the best ways known to the applicants of putting the invention into practice. However, they are not the only ways in which this can be achieved.

The present embodiments relate to the development of discrete, fast-operating, LS-OFETs and electro-optical circuits for switching and sensing applications. In particular, we envision the use of such devices in a range of applications spanning from discrete LS-OFETs and colour/image sensing arrays, to opto-electrical circuits (analogue/digital) in which signal processing involves the use of both optical and electrical signals. For light sensing applications our approach offers advantages over traditional organic photodiodes, mainly due to the potential of higher operating speeds (lower RC constants) but also due to the manufacturing simplicity of the discrete LS-OFET and hence the sensing array. Furthermore, our technology can combine the driving electronics and the sensing elements in a single bifunctional circuit without the need of a traditional sensing photodiode. To the best of our knowledge no such opto-electrical circuits or sensing arrays have yet been demonstrated in the open literature. During the past twenty years progress in the area of OFETs and organic integrated circuits (ICs) has been mainly driven by materials developments rather than developments on device and circuit concepts.[7] Noticeably, use of OFETs has been restricted to applications in which the transistors are used purely as unifunctional devices, notably in pixel engines for active-matrix flexible displays and large-scale digital ICs[1], to name a few.

Of particular interest are recent demonstrations of LS-OFETs by several research laboratories around the world.[3],[8],[9] A distinct characteristic for the majority of these devices is that they rely on the photoconductive effect. Recently, however, LS-OFETs based on different photogeneration mechanisms, such as the photovoltaic effect, have also been reported.[10] In these devices, photoresponse is a result of photogenerated mobile charges induced by the absorption of incident light upon which the conductance of the transistor channel increases. Hence, by modulating the amount of photogenerated carriers, either by controlling the amount or wavelength of the incident radiation, one can in principle control the electrical current flowing through the transistor channel. Hence, fabrication of an electro-optical type switch is possible.

LS-OFETs define a new class of organic electro-optical devices and can be considered as a new type of optical transducer requiring a combination of both good photovoltaic properties and high transistor performance. The highly attractive feature of these devices is that they combine light detection and signal amplification functions in a single structure without the noise increment associated with different type of detectors such as avalanche photodiodes. Moreover, the intrinsically small geometrical capacitance (compared to photodiodes) makes LS-OFETs strong candidates for application as high-frequency electro-optical switches. An additional advantage is that a vast library of organic semiconductors with tailor-made physical characteristics is, theoretically, accessible. Making use of the latter one can, in principle, design LS-OFETs with unconventional or customised operating characteristics, including wavelength selective capabilities. Integration of several such LS-OFETs may lead to fabrication of sensor arrays with a spectral response that mimics the response curve of the human eye, without the need of expensive fabrication processes typically required for inorganic detectors such as charge coupled devices (CCD) and complementary-metal-oxide-semiconductor (CMOS) image sensors. Despite their great potential, however, LS-OFETs have not previously been given significant consideration.

### 1. An Introduction to LS-OFETs

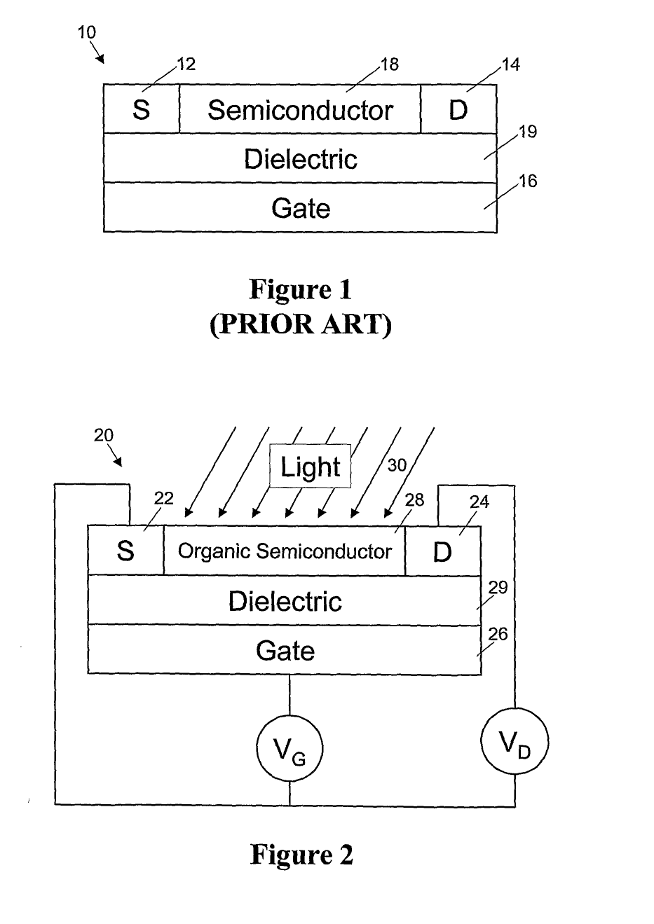

By way of background, and for comparison with OFETs, FIG. 1 shows a schematic illustration of a typical semiconductor field-effect transistor (FET). The transistor 10 comprises a source electrode 12, a drain electrode 14, and a gate electrode 16. The source electrode 12 and drain electrode 14 are separated by a semiconductor 18, typically silicon, germanium or gallium arsenide. The semiconductor material is doped to provide electrons as the majority carrier (forming an “n-type” semiconductor) or holes as the majority carrier (forming a “p-type” semiconductor). The gate electrode 16 is separated from the semiconductor 18 by a dielectric layer 19. Electron flow from the source 12 to the drain 14 is triggered by the application of a voltage to the gate 16.

A basic schematic LS-OFET structure is illustrated in FIG. 2. The LS-OFET 20 consists of a source electrode 22, and drain electrode 24, an organic semiconductor (OS) 28, a conductive gate 26, and a dielectric layer 29. Under normal operation the channel current (I_{D}) that flows from the source electrode 22 to the drain electrode 24 can be either switched ON or OFF depending on the gate potential (V_{G}) at a constant drain potential (V_{D}). The polarity of V_{D}, V_{G} and I_{D} depend on the type of the semiconductor employed, i.e. electron (n-type) or hole (p-type) transporting. In an n-type OFET for example, V_{D} and V_{G} have to be biased positively in order to have electron accumulation in the channel, and vice versa.

### 2. Development of Discrete High-Performance LS-OFETs

In recent years there has been a high level of interest in the use of organic semiconductors for optoelectronic applications leading to an eminent progress in the field. Most of the interest was directed to solar cells and light-emitting diode devices, due to their potential for low-cost, large area, flexible applications. In comparison to these devices, organic photodetectors have received very little attention with the majority of the demonstrated devices being based on vertical-type photodiodes.[12] Although organic photodiodes posses the desirable characteristics of high gain and high quantum efficiency, the dark current increases significantly with increasing bias voltage leading to considerable amount of excess noise while at the same time reducing the dynamic range of the detector. Moreover, the large intrinsic capacitance of diode-type photodetectors severely limits their operating bandwidth.

LS-OFETs based on the photovoltaic effect on the other hand exhibit low dark currents and low RC due to their planar geometry, thus making them good candidates for application in optoelectronics. Furthermore, LS-OFETs offer the possibility of higher sensitivity by virtue of the internal current gain of the transistor structure, resulting in a high signal-to-noise ratio with respect to organic photodiodes. Even from the view point of device design, fabrication and large-scale integration, photosensitive organic transistors offer numerous advantageous features over organic photodiodes. Despite their great advantages, however, only a handful of LS-OFETs have previously been demonstrated.

### 2.1 An Ambipolar LS-OFET Having Improved Transfer Characteristics

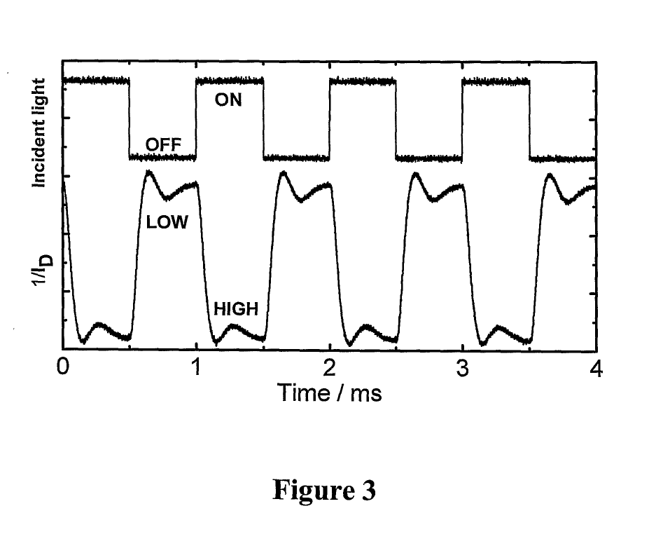

If the OS layer 28 of the LS-OFET structure illustrated in FIG. 2 is replaced by an appropriate ambipolar layer (capable of transporting both electrons and holes as carriers) with good carrier photogeneration efficiency (using the photovoltaic effect) then the channel current can be switched ON or OFF not only by the V_{D} and V_{G} potentials but also by the presence or absence of an external light signal 30. An example of this effect is shown in FIG. 3, where the I_{D} current of an ambipolar OFET (the lower trace) is modulated by an external light signal (the upper trace). Note that the lower trace is the inverse of the I_{D} magnitude. Thus, in principle, an LS-OFET can be used as an electro-optical switch.

Demonstration of some LS-OFET switches has already been reported in the literature, e.g. by Marjanović et al.[3], with varying operating performance and different device structures. However, the LS-OFETs demonstrated by Marjanović et al., although based on ambipolar organic blends, do not in fact exhibit ambipolarity in their transfer characteristics. As previously mentioned, in FIGS. 2 and 3 of Marjanović, the channel current I_{D} increases rapidly with gate voltage magnitude when the gate voltage is positive, but shows little or no increase with gate voltage magnitude when the gate voltage is negative.

In the present embodiments we have modified the device structure and optimised the operating speed of OFET transistors. This is achieved by using (a) an optimised ambipolar organic blend as the semiconductor, together with (b) the fabrication of transistors having a reduced channel length. In this way, photogenerated charge carriers can be transported across the channel more efficiently and faster, thus further enhancing the device current. Furthermore, a single type of ambipolar organic semiconductor may also be employed as the electroactive layer.

The two techniques mentioned above, namely (a) the use of an optimised ambipolar organic blend as the semiconductor, and (b) the fabrication of transistors having a reduced channel length, will now be described in more detail:

### 2.1.1 Use of an Optimised Ambipolar Organic Blend as the Semiconductor

We have produced some LS-OFETs based on single layer heterogeneous blends consisting of n- and p-channel semiconductors, thereby forming bulk heterojunction LS-OFETs. For example, blends of fullerene derivatives (or other soluble small molecules) with hole transporting polymers are known to exhibit the highest photogeneration efficiency.[11] The fullerene derivative provides n-type behaviour (i.e. provides electrons), and the polymer provides p-type behaviour (i.e. provides holes). Blended together, ambipolar transport activity can be observed. To the best of our knowledge, LS-OFETs based on a single component ambipolar semiconductor layer have never before been demonstrated.

Moreover, we have found that some of our LS-OFETs exhibit high photosensitivity with fast frequency response. In our presently preferred embodiment, we use an ambipolar layer comprising a blend of fullerene derivative ([60]PCBM) and an organic polymer (OC₁C₁₀-PPV).

We have found that, by using a blended ambipolar layer in which the fullerene:polymer ratio is 20:1 by weight, excellent light detection characteristics can be obtained from the LS-OFET. (As is mentioned below, other fullerene:polymer ratios, such as ratios throughout the range of from 8:1 to 20:1, were also found to work well.)

Our compositions are radically different from that disclosed by Marjanović et al.[3], in which the fullerene:polymer ratio is 4:1 by weight. Another standard composition known from the prior art has a fullerene:polymer ratio of 3:1 by weight.[10]

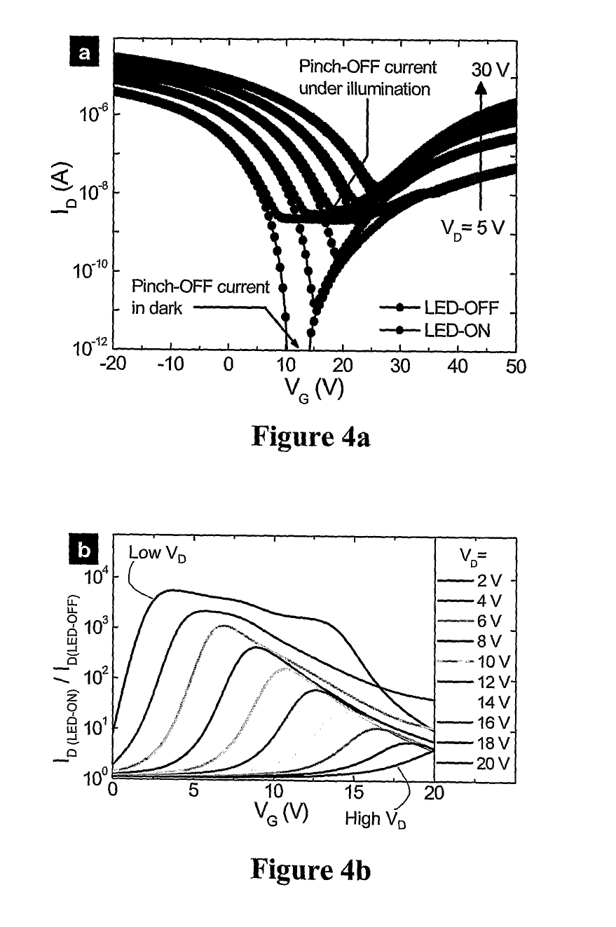

FIGS. 4a and 4b illustrate typical experimentally-measured transfer characteristics for our ambipolar LS-OFET having a heterogeneous blend [60]PCBM:OC₁C₁₀-PPV. In FIG. 4a, values of I_{D} are plotted against the gate voltage V_{G}, for different values of the drain voltage V_{D} ranging from 5 V to 30 V. Measurements were performed under darkness (finer trace) and under constant illumination (broader trace) using an inorganic blue GaN-based LED. As can be seen, a large increase in the transistor pinch-OFF current is observed under illumination.

FIG. 4b shows the photocurrent modulation ratio of the device, i.e. the ratio of photocurrent (I_{D}(LED-ON)) to dark current (I_{D}(LED-OFF)) calculated at different biasing regimes. I_{D} values measured with the blue LED ON, divided by the I_{D} values measured with the blue LED OFF, are plotted against the gate voltage, V_{G}. As can be seen, the current modulation is high and strongly dependent on V_{G} and V_{D} potentials, as well as on the intensity and wavelength of the incident light (data not shown). By making use of this property we are able to fabricate and dynamically characterise solution processed LS-OFETs (under pulsed-light operation) with switching frequencies of several kHz. To the best of our knowledge this is the fastest LS-OFET operation reported to date in the open literature.

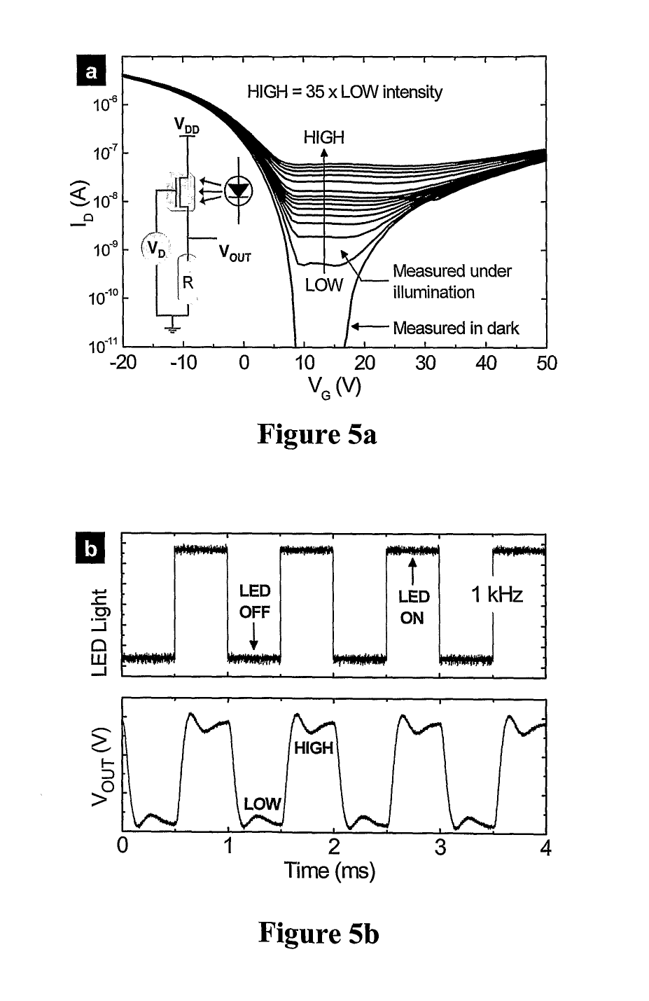

Further experimental results are shown in FIGS. 5a and 5b. In FIG. 5a, the transfer characteristics of the LS-OFET were measured in darkness, and under pulsed light illumination at different intensities, at V_{D}=5 V. The inset within FIG. 5a illustrates the circuitry of the measurement set-up employed. The lower trace of FIG. 5b illustrates the evolution of the drain current (I_{D}), measured at constant V_{D}, versus time, under pulsed excitation with light (upper trace) produced using the blue LED.

When the LED was driven in a pulse mode (FIG. 5b, upper trace) the current flowing through the LS-OFET channel was modulated (FIG. 5b, lower trace) and the transistor functioned as an electro-optical switch. The maximum switching speed measured in this specific LS-OFET was of the order of 3 kHz. This is faster than any organic phototransistor reported in the literature to date.

As FIGS. 4a and 5a show, this LS-OFET exhibits ambipolarity in its transfer characteristics, with there being an increase in the channel current I_{D} for increasing magnitudes of gate voltage in either the positive or negative sense. This represents a significant improvement over the prior disclosure of Marjanović et al.[3], since it enables rapid reversible switching, without the hysteresis effect exhibited by Marjanović.

By using a fullerene:polymer ratio of 20:1 by weight, rather than the ratio of 4:1 disclosed by Marjanović et al, it is considered that approximately equal mobility of electrons and holes is enabled through the ambipolar layer, and that this consequently enables the LS-OFET to exhibit ambipolarity in its transfer characteristics.

Thus, for optimum performance, the composition of the ambipolar layer may be tailored such that the mobility of holes is substantially equal to the mobility of electrons. This is because, upon photoexcitation, generated holes and electrons will have to travel across the channel and be collected by the corresponding electrodes. If one of the carriers is slower than the other, then the photogenerated current will be lower than its optimal value and hence the signal detected will be smaller. Therefore, to improve this, we design the transistors with component concentrations such that the mobility of both carriers are approximately equal.

The ratio of 20:1 is not absolute and will depend on the physical properties of the two semiconductors (molecular weight, film forming properties etc). For the particular blend of [60]PCBM:OC₁C₁₀-PPV, the optimum performance was found to come from the 20:1 concentration. However, a broad range of percentage weights are suitable, and other concentrations such as from 8:1 up to 20:1 also work very well, and give approximately similar results to those obtained with the composition of 20:1. With other fullerene:polymer ratios, such as from 8:1 up to 20:1, the characteristics also depend on the way the films are processed.

If the blend components change, for example if instead of OC₁C₁₀-PPV we employ various polythiophene derivatives such as P3HT, then the optimum concentration is expected to change too.

Expressed generally, by optimising the composition of the ambipolar layer, we can obtain OFETs which exhibit an optimised photovoltaic effect.

Details of a fabrication process which may be used to make such a device, including the production of an ambipolar layer, are given in reference [4], the relevant content of which is incorporated by reference herein.

The embodiment described above may be modified to further improve the responsivity and switching characteristics of LS-OFETs. To achieve this, molecules with improved transport properties may be used. Candidate materials include novel high electron mobility (>0.1 cm²/Vs) perfluorinated fullerene derivatives (Solenne B.V.) in combination with high hole mobility polymers (Merck Chemicals Ltd). The component concentration and film structure may also have an effect. For instance, photogeneration of free carriers is known to be more efficient at lower fullerene concentrations, but this effect is cancelled out due to reduction of the electron mobility.[13] Moreover, the morphology of solution processed blend films is determined by the thermodynamics and kinetics involved in film formation and post-treatment.

### 2.1.2 Fabrication of Transistors Having a Reduced Channel Length

The channel length in an LS-OFET is determined by the distance from the source 22 to the drain 24. We have found that, by reducing the channel length to approximately 0.5 μm to 50 μm, preferably to approximately 1 μm to 2 μm, this significantly increases the switching speed of the LS-OFET. Such short channels may be achieved by photolithography techniques, rather than by using the shadow masking technique that is generally used in the prior art. Some sensing circuits may be fabricated using more relaxed designs rules, i.e. longer channel lengths, which enable the use of alternative low cost fabrication techniques such as printing etc.

### 2.1.3 Detailed Fabrication Process for Short Channel LS-OFET

The detailed fabrication process used to make the present devices is described in references [4] and [16], the relevant contents of which are incorporated by reference herein. In summary, the substrate of the devices also acts as the gate electrode (a common gate for all transistors in the chip) and is made using highly conductive doped Si⁺⁺ silicon wafers. The Si⁺⁺ wafers are then thermally oxidised under suitable conditions to form an insulating layer of SiO₂ having a thickness of the order of 300 nm. Next a thin layer (10 nm) of chromium (Cr) is deposited, acting as an adhesion layer for gold that is deposited straight after. The thickness of the gold layer can vary and typically is in the order of 100 nm. Then the gold layer is structured to S-D electrodes using standard lift-off photolithography. The channel length can vary between 0.5 μm and hundreds of μm. Once electrode patterning has been completed the structure is exposed to vapours of a self-assembling monolayer, namely hexamethyldisilazane (HMDS). The latter self-assembles on the surface of SiO₂ making its surface hydrophobic. If the HMDS is not applied the carrier mobility of the semiconductor material is very low. Thus the HMDS layer acts as a passivation barrier and can be replaced by a number of other passivation layer materials. In the case of polymeric dielectrics, however, no such passivation layer is required. For the present LS-OFET application we chose 1-2 μm channel lengths, since the distance that the generated carriers must travel before they are collected by the S-D electrodes is short, and hence the frequency response of the device is very high. Longer channel lengths will also work, but the time response of the device would be expected to be slower. Finally the organic blend of PCBM:PPV is deposited on the top of the prefabricated structures using spin coating. For this particular structure the spin speed was 1000 revolutions per minute.

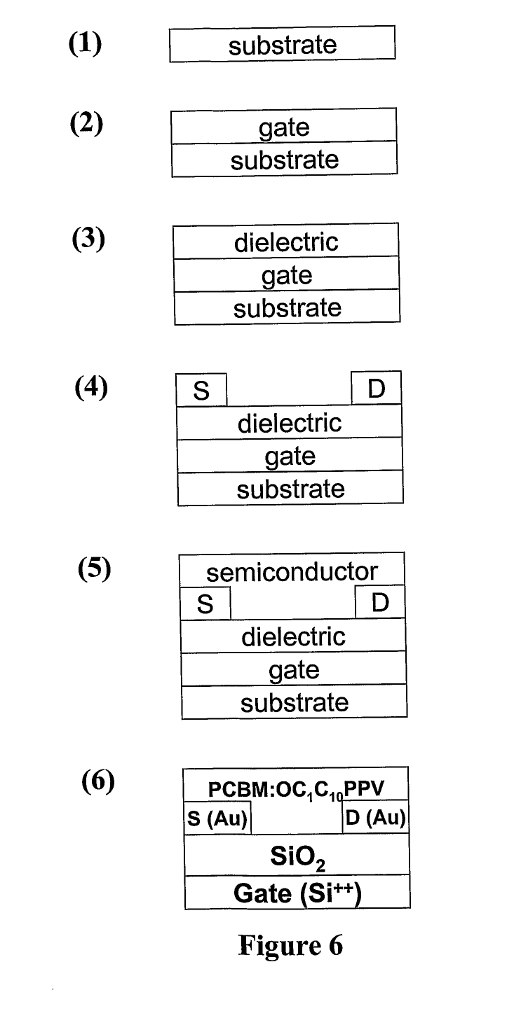

The fabrication steps are illustrated in FIG. 6, as follows:

Step (1): The substrate can be rigid or flexible depending on the application.

In the present embodiment we employ doped silicon that also acts as the transistor gate, but this could be replaced by other materials.

Step (2): If the substrate is not conducting then a conductive gate has to be deposited. This can be a conductive polymer, metal, or any type of solid conductive substance (e.g. silicon etc). In the present embodiment the gate is made using conductive doped silicon. However, flexible gates and substrates could also be used, made of metal foil or plastic, which would enable fabrication of flexible devices or arrays.

Step (3): The dielectric is then deposited on the top of the gate. This is the standard process for a bottom contact, bottom gate OFET. In the present embodiment the dielectric is standard thermally-grown SiO₂. However this layer can be any inorganic material having good insulating properties or similarly-performing organic materials (small molecules, oligomers and polymers).

Step (4): The source and drain contacts (“S” and “D”) are then deposited on the top of the dielectric. In the present embodiment the source and drain contacts are made using gold electrodes, employing standard photolithography techniques. However, other contact metals may alternatively be employed, as those skilled in the art will appreciate.

Step (5): Finally, the semiconductor is deposited on the top of the prefabricated structure, either by solution processing or thermal evaporation. In the present embodiment the organic blend is deposited by spin coating of the blend at room temperature in ambient conditions.

Diagram (6) of FIG. 6 illustrates the actual device structure used for the LS-OFETs of the present embodiment. It should be noted that the HMDS passivation layer is not shown since it is very thin (˜1 nm) and does not play any electroactive role.

### 2.1.4 Other Design and Fabrication Factors

Other design and fabrication factors have been found to improve or contribute towards the performance of the blended ambipolar LS-OFET described above. As well as the use of the optimised ambipolar organic blend as the semiconductor, and the fabrication of a short channel length of approximately 0.5 μm to 50 μm (preferably approximately 1-2 μm), other currently-preferred design and fabrication features of our blended ambipolar LS-OFET are as follows:
High quality, high smoothness SiO₂ dielectric substrate
Highly conductive doped silicon gate
Deposited source and drain electrodes
Structure formed by photolithography (or printing could alternatively be used if the channel is long enough).

Instead of forming the structure by photolithography, alternative processes are possible, include solution processing techniques (e.g. various printing techniques, spin coating or thermal evaporation) or thermal sublimation techniques.

It should be noted that device structures having alternative contact/gate configurations may be employed, as those skilled in the art will appreciate. Examples of alternative structures are: bottom-contact bottom-gate structure; bottom-contact top-gate structure; top-contact top-gate FETs; or asymmetric S-D contact configuration structures. This applies throughout the present disclosure, to all the embodiments described herein.

### 2.2 Alternative LS-OFET Device Architectures

LS-OFETs based on device architectures other than the bulk heterojunction LS-OFET described above may alternatively be produced.

### 2.2.1 Heterostructure LS-OFETs

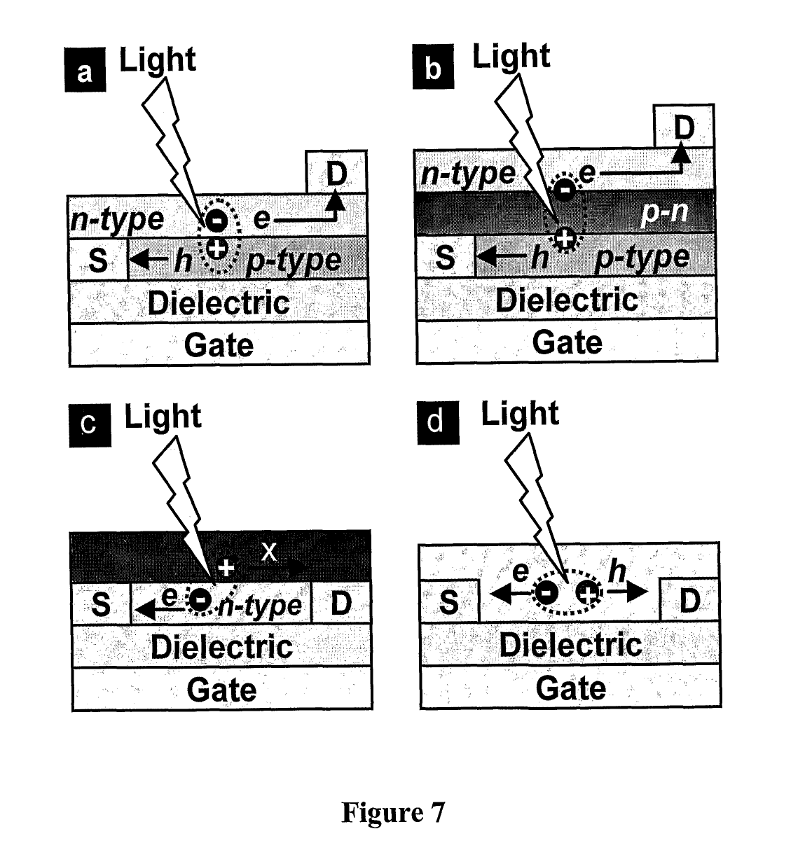

One such device structure is a bilayer p-n type heterostructure OFET, as illustrated in FIG. 7a. This is known to exhibit promising ambipolar transport [14] and is therefore expected to be suitable for use as LS-OFETs.

The key characteristic of this architecture is the incorporation of p-, and n-type organic semiconductors for the creation of an abrupt p-n junction where excitons can be dissociated after photoexcitation. Shortly after an exciton is formed it diffuses to the junction and dissociates due to the strong built-in potential across the junction, yielding two free charge carriers, a hole and an electron. Driven by the applied electric field between the S-D electrodes, photogenerated holes and electrons are transported, through the p- and n-channel layers, respectively, to the corresponding collecting electrodes. The key advantage of heterostructure LS-OFETs is that charge transport along the p- and n-channel layers is optimised and photogenerated carriers can be rapidly transferred to the corresponding collecting electrode. Therefore a faster switching response may be obtained. No such device has yet been reported in the open literature.

### 2.2.2 Multilayer LS-OFETs

Another promising LS-OFET structure is the multilayer LS-OFET, as illustrated in FIG. 7b. The latter is a modified version of the p-n heterostructure concept in which a high photogeneration efficiency interlayer is incorporated in-between the p- and n-transport layers. Upon illumination of the device, exciton formation and subsequent dissociation to free carriers within the photogeneration interlayer occurs. Free carriers are then rapidly transferred to the corresponding p- and n-transport layers and eventually to the collecting electrodes. The potentially key advantage of this device architecture is that it combines the high photogeneration efficiency of the bulk-heterojunction systems with the optimised transport characteristics of the p-n heterostructure transistor. We note that no such device has yet been demonstrated in the open literature.

### 2.2.3 Unipolar Light-Sensitized LS-OFETs

LS-OFETs architectures with reduced fabrication complexity may also be exploited. An example of such device is shown in FIG. 7c. Here a high-mobility unipolar transistor is fabricated employing a photosensitizer layer on the top of the transistor channel where free carriers are generated upon photoexcitation. In the case of an n-channel OFET, for instance, photogenerated electrons will be transferred from the photosensitizer bulk/interface to the electron conducting channel leading to current enhancement. Although such a device is expected to have improved switching characteristics, due to high unipolar carrier mobility, its responsivity is expected be lower as compared to ambipolar LS-OFETs. This is mainly due to the contribution of only one type of charge carriers leading to reduced current enhancement. No such device has yet been demonstrated in the open literature.

### 2.2.4 Narrow Bandgap LS-OFETs

Ambipolar OFETs based on narrow bandgap organic semiconductors[5],[6] may also be utilised. The device structure of such LS-OFETs is shown in FIG. 7d. Here an ambipolar organic semiconductor is employed together with conductive S-D electrodes, although any suitable device structure could, in principle, be used. In this device, free carrier photogeneration and transport occurs within the same semiconductor material. Candidate molecules which may be exploited include various dithiolene[5] and squaraine[6] derivatives. Although our early study (unpublished) on these systems show only moderate photosensitivity to date, the devices exhibit interesting spectral response with detection wavelengths in the near IR region. This absorption characteristic makes narrow bandgap LS-OFETs attractive for applications in optical telecom systems and near-IR image sensor arrays. No similar device has yet been demonstrated in the open literature.

### 2.2.5 Wavelength-Selective LS-OFETs

In order to further exploit the bifunctional nature of LS-OFETs, devices may be fabricated with wavelength-selective capabilities. The aim is to fabricate transistors with relatively narrow spectral response for use in integrated sensor arrays like image sensor devices. The adaptation of the wavelength-selective concept in LS-OFETs incorporates two advantageous features. First, use of LS-OFETs increases the degrees of freedom for use in optoelectronic and sensing applications as these devices can be integrated using standard photolithography and various printing or other techniques. Second, the approach fully enjoys the benefits of easy processing that organic semiconductors offer.

Possible routes which may be exploited include the use of materials with suitable absorption and transport characteristics in combination with the different device architectures of FIG. 5 or alternative structures. For example, heterogeneous blends (polymer:fullerene) may be used in the fabrication of LS-OFETs with wavelength response in the range of 300-500 nm.[11],[13] Ambipolar single layer LS-OFETs based on F8BT may be used in devices with wavelength response in the range 450-700 nm, while narrow bandgap LS-OFETs may be employed for photoresponse in the region 700-1200 nm. Alternative device structures incorporating external optical bandpass filters may also be produced when molecules with suitable wavelength-selective physical characteristics cannot be identified.

To fabricate these LS-OFETs, organic semiconductors may be obtained from commercial sources. For instance, high mobility electron transporting fullerenes may be obtained from Solenne B.V. High mobility hole transporting polymers may be obtained from Merck Chemicals Ltd. Narrow bandgap molecules such as dithiolenes[5] and squaraines[6] may be obtained from Sigma-Aldrich or Sensient.

### 3. Potential Applications in Electro-Optical Switches and Circuits

The demand for electro-optical devices that combine the properties of photonic structures with those of traditional semiconductor devices is continuously increasing due to their numerous new applications. In optical telecommunications, for instance, information is transmitted through an optical fibre and subsequently converted into an electrical signal at a receiver using an electro-optical switch. The transmitted optical signal on the other hand does not play any role in the signal processing. Development of low-cost electro-optical switches and electro-optical integrated circuits that are capable of performing signal processing using optical and electrical signals can therefore greatly benefit the wide field of optical communication and lead to novel applications.

The high-performance LS-OFETs described above have the potential to enable the design and fabrication of such devices and circuits at ultra low cost by taking advantage of the unique processing properties of organic semiconductors. Although one may argue that organic-based photodetectors may never be able to compete with their inorganic counterparts for use in high-performance applications such as fibre telecommunication networks, they could be ideal for use in various less-demanding applications such as in the automotive industry, and in particular in “in-vehicle fibre-optic networks” where low-cost, relatively low-bandwidth links (10 Mbit/s) are required. For example, nearly all today's top-of-the-range cars use plastic optical fibres (POF) to connect up the ever-increasing number of in-car electronics. POF offers a rugged platform (as needed in the automotive sector) together with ease of installation and fault finding. Crucially, POF is also a low-cost system option that comes in at a fraction of the cost of their pure silica counterparts. Development of LS-OFETs based electro-optical switches employing a POF compatible technology (polymer processing etc.) therefore has the potential to dominate this emerging market.

Inter alia, we envisage the use of LS-OFETs in electro-optical switches and circuits. These will now be discussed.

### 3.1 Electro-Optical Switches Based on LS-OFETs

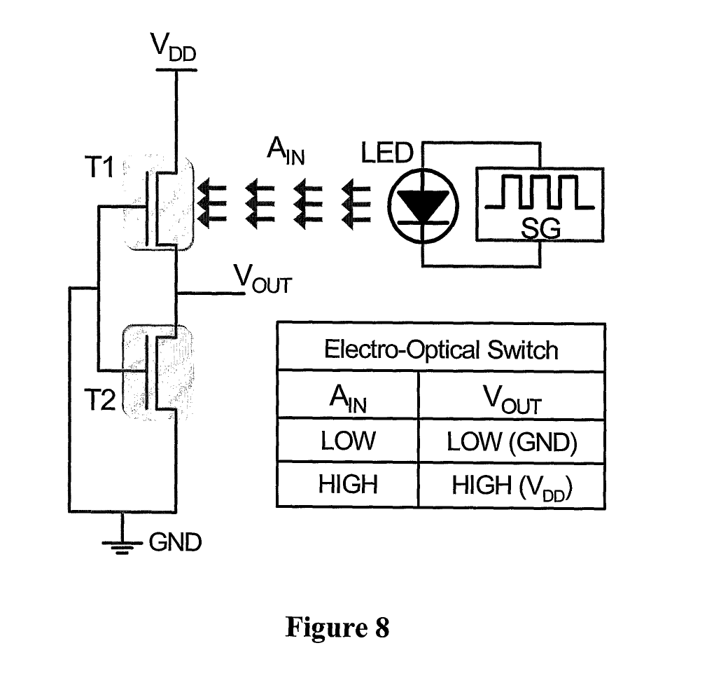

The basic function of an electro-optical switch involves the detection of an optical input signal (or its absence) and its conversion to an electrical signal at the output. FIG. 8 illustrates an electro-optical switch based on an ambipolar LS-OFET (T1) and a unipolar OFET (T2) integrated in a complementary layout. A square pulse signal generator (SG) is used for driving a GaN based LED in a pulse mode.

When the optical input signal (A_{IN}) is LOW (i.e. no light) the impedance of T1 (R_{TI}) is higher (×10) than that of T2 (R_{T2}) leading to a low voltage output (V_{OUT}=GND [LOW]). When A_{IN}=HIGH (i.e. an optical signal is present) then R_{T1}<<R_{T2} and V_{OUT}=V_{DD} (HIGH). The truth table of the circuit is also shown in FIG. 8, and shows the binary states of the circuit output at HIGH and LOW input signals.

We note, however, that A_{IN} and V_{OUT} are not only restricted to the binary states of HIGH and LOW, but they may also contain analogue information. For example, the circuit of FIG. 8 can be designed such that V_{OUT} is proportional to the intensity of A_{IN}. This means that analogue information contained in the optical input may also be converted to electrical signals at the output.

The electro-optical switch of FIG. 8 offers several added advantages over conventional photodetector-based switches. First, the response time is expected to be faster due to lower RC constants, and secondly it does not require additional fabrication steps for the processing of the driving electronics since this is a built-in feature of the circuit. Moreover, noble metal electrodes (e.g. Au, Pt, Ag) can be employed for S-D contacts, thus avoiding the need for oxidatively unstable low-workfunction metals (e.g. Al, Ca, Ba) typically employed in organic photodiodes. Finally, the circuits can be designed using (but not limited to) standard CMOS processes, therefore simplifying further the fabrication process. The response time of the latter will depend on the ambipolar carrier mobility in the semiconductor(s) and the lateral dimensions of the transistor. Optimised circuits may be designed and fabricated employing the best performing LS-OFETs, for example the optimised LS-OFET described above.

### 3.2 Electro-Optical Logic Circuits Based on LS-OFETs

Electro-optical switches based on LS-OFETs are envisaged to pave the way towards electro-optical integrated circuits. Such circuits should be capable of executing a logical operation in response to a combination of optical and electrical inputs and outputting a result in the form of an electrical signal. The properties of electro-optical circuits are not exactly parallel to those of electronic circuits so many new applications can be envisioned.

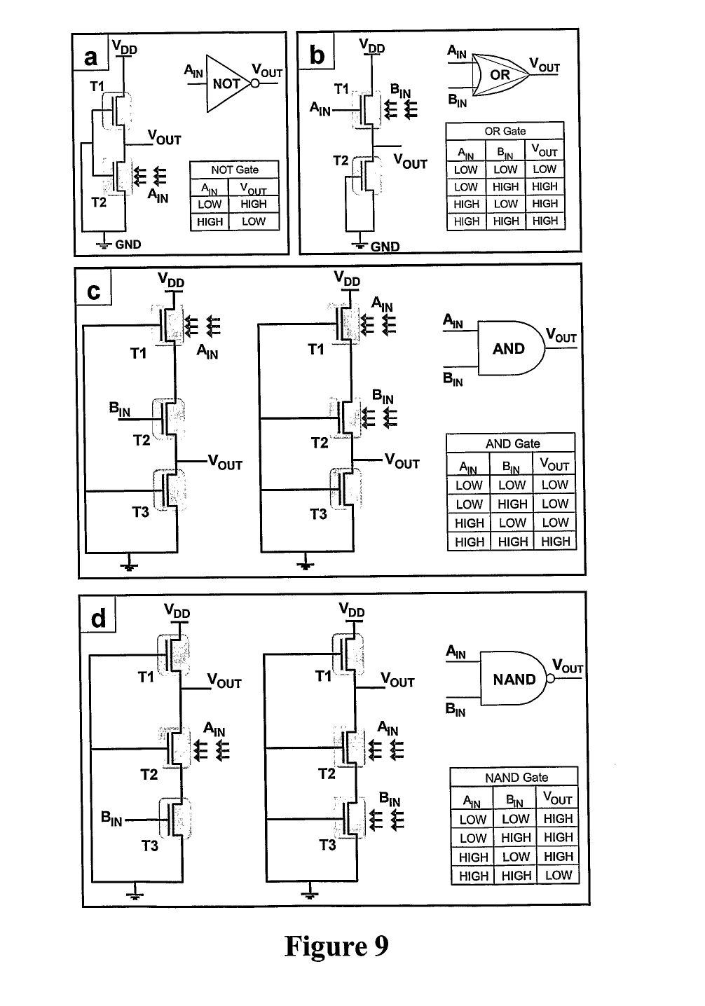

FIG. 9 shows various electro-optical logic gates which may be fabricated using the LS-OFETs described above, together with unipolar OFETs.

The proposed circuitry of a NOT gate, comprising an LS-OFET and a unipolar OFET, is shown in FIG. 9a. Here, when A_{IN}=HIGH (high light intensity), the impedance of T2 (R_{T2}) reduces to a value lower than that of T1 (R_{T1}), leading to V_{OUT}=GND (LOW). When A_{IN}=LOW, then R_{T2}>>R_{T1} and V_{OUT}=V_{DD} (HIGH). The output of the NOT gate may be used to create a binary signal, or analogue information such as the intensity of the incident light may be retained.

By modifying the circuit layout an OR gate can also be designed. An example is illustrated in FIG. 9b. Here the circuit combines two inputs; one electrical (A_{IN}) and one optical (B_{IN}). When either of the two inputs is HIGH, R_{T1}<<R_{T2}, resulting in V_{OUT}=V_{DD} (HIGH) since the voltage drop across T1 is negligible. When both of the input signals are LOW then R_{T1}>>R_{T2} and V_{OUT}=GND (LOW), since most of the voltage drop occurs across T1.

Other electro-optical logic gates can also, in principle, be designed using more complex circuit layouts. Typical examples are the AND and NAND gates shown in FIGS. 9c and 9d respectively. By modifying the circuit layout of these gates, the nature of the input signals may also be changed from a combination of one optical (A_{IN}) and one electrical (B_{IN}) input signals, as shown in the left hand side circuit in each case, to two optical inputs as shown in the right hand side circuit in each case. The same principle may be applied to the OR gate described above. For circuits having two optical inputs, two LS-OFETs are required. The two LS-OFETs may be responsive to different wavelengths of incident light, thereby enabling logical processing operations to be performed based on wavelength.

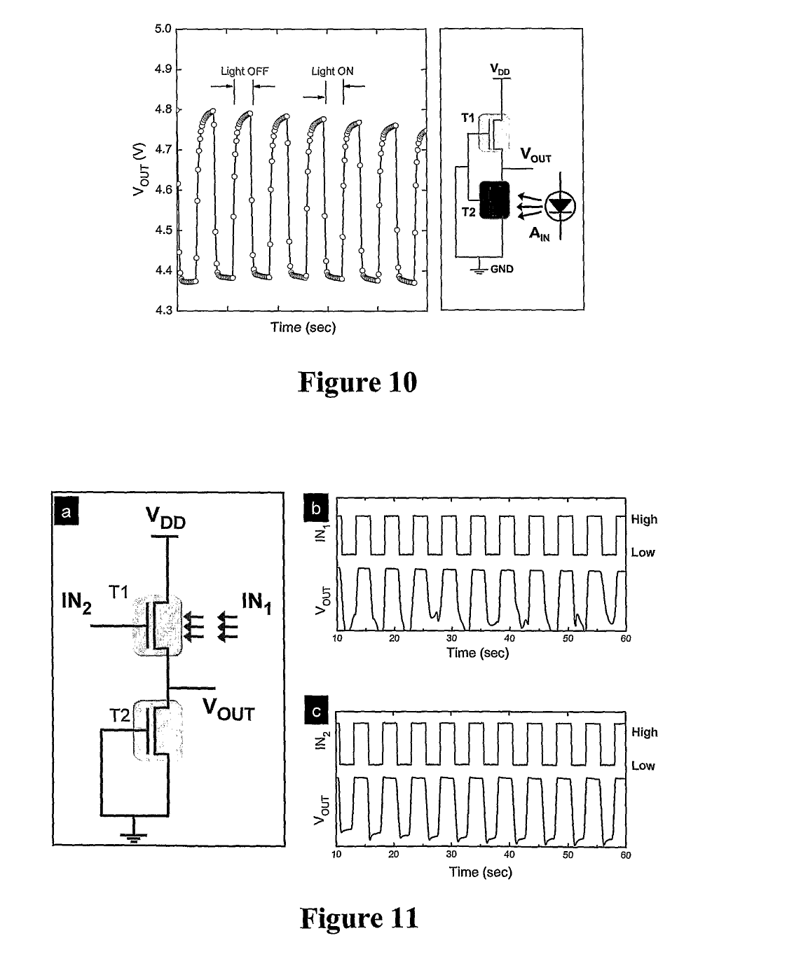

We have performed some experimental work to demonstrate functional electro-optical circuits based on LS-OFETs consisting of PCBM:OC₁C₁₀PPV. The device structure used for the fabrication of these circuits is similar to the one shown in diagram (6) of FIG. 6. FIG. 10 shows the operation of an electro-optical inverter (NOT gate) in which the input signal is optical and the output signal is electrical (as in FIG. 9a). In FIG. 10, transistor 1 (T1) is an ordinary unipolar transistor without appreciable optical response. T2 is an LS-OFET based on a blend of PCBM:OC₁C₁₀PPV. The specific circuitry that was used is not fixed, and can differ depending the operating/design characteristics of the two transistors. With this circuit, from the results plotted in FIG. 10, it can be seen that when the input signal (A_{IN}) is HIGH (i.e. light ON) the output signal (V_{OUT}) is LOW, and when the input signal (A_{IN}) is LOW (i.e. light OFF) the output signal (V_{OUT}) is HIGH. Therefore, it is evident that the input optical signal has been inverted from a HIGH state to a LOW voltage state at the output, and vice versa.

In addition to the NOT gate shown in FIG. 10, we have also been able to demonstrate an electro-optical OR gate as shown in FIG. 11a, in which one input signal is optical (IN₁) and the second one electrical (IN₂). FIG. 11b shows the output signal of the gate (V_{OUT}) as a function of the optical input signal (IN₁). As can be seen, when IN₁ is HIGH the V_{OUT} is HIGH too. FIG. 11c shows the output signal of the gate (V_{OUT}) as a function of the electrical input signal (IN₂). Again, when IN₂ is HIGH the V_{OUT} is HIGH too. So, in summary, when either of the two input signals (i.e. the optical and/or the electrical) is HIGH, the electrical output signal is HIGH too, in accordance with the OR truth table shown in FIG. 9b.

The basic electro-optical logic gates illustrated in FIGS. 9a to 9d may be combined to produce more complex logic gates and more complex signal processing apparatus.

As mentioned above in connection with electro-optical switches, the electro-optical logic gates may be used to perform analogue signal processing operations as well as binary operations. Thus, light intensity and wavelength information may be captured and processed.

The spectral response of the LS-OFETs can be modified at will by using appropriate organic semiconductors with different absorption characteristics or by introducing filters (which may be absorptive or reflective). Ambipolar LS-OFETs based on a single semiconductor are the preferred option. Logic gates and analogue circuits with different spectral response (wavelength selectivity) for each input signal are possible. For example, in a simple form, the NOT circuit in FIG. 9a can be adapted to respond only to certain light wavelengths (e.g. in the visible or in the near IR), either by the use of different organic semiconductors or with the aid of optical filters (which may be external or integrated on the device/array structure). Therefore, an array of sensing circuits with multi-wavelength detection capabilities is possible. Such an array could be used in colour or image sensing applications, including pattern recognition, security display testing, printing quality control and the like, and has great technological potential. An added advantage is that, by using the electro-optical circuits of FIG. 9, we can integrate the reading/addressing electronics with the sensing elements without the need of additional processing steps.

Thus, by integrating wavelength-selective LS-OFETs as discussed above with the circuits of FIG. 9, circuits can be fabricated where the optical input is not only characterised by its binary/analogue state but also by its characteristic spectrum and/or intensity. Such multi-wavelength detection circuits could have numerous applications including in-vehicle fibre-optic networks where multiple optical signals are transmitted through the same POF and decoded by a single sensor array consisted of several wavelength-selective LS-OFETs.

Other potential applications include image sensing devices, which will now be discussed.

### 3.3 Image-Sensing Arrays Using LS-OFETs

Image sensors are devices capable of converting an optical image into a digital image. Image capture in today's digital cameras is achieved using charge coupled devices (CCDs) or CMOS sensor arrays for small area imaging, and amorphous silicon for large area imaging (e.g. x-ray imaging). Although very successful, inorganic sensors are complex with high manufacturing cost. In this respect organic semiconductors provide interesting new opportunities and substantial amount of interest has been directed to using these materials in sensor arrays.[15]

As has already been discussed, the LS-OFETs described above offer the interesting possibility of being integrated with the driving electronics as part of the same process without the need of extra fabrication steps typically required in photodiode-based sensors. Hence fabrication of low-cost, large-area image sensors with fast response should be possible using solution-processing techniques based on the same procedure as used in state-of-the-art organic circuits.[1]

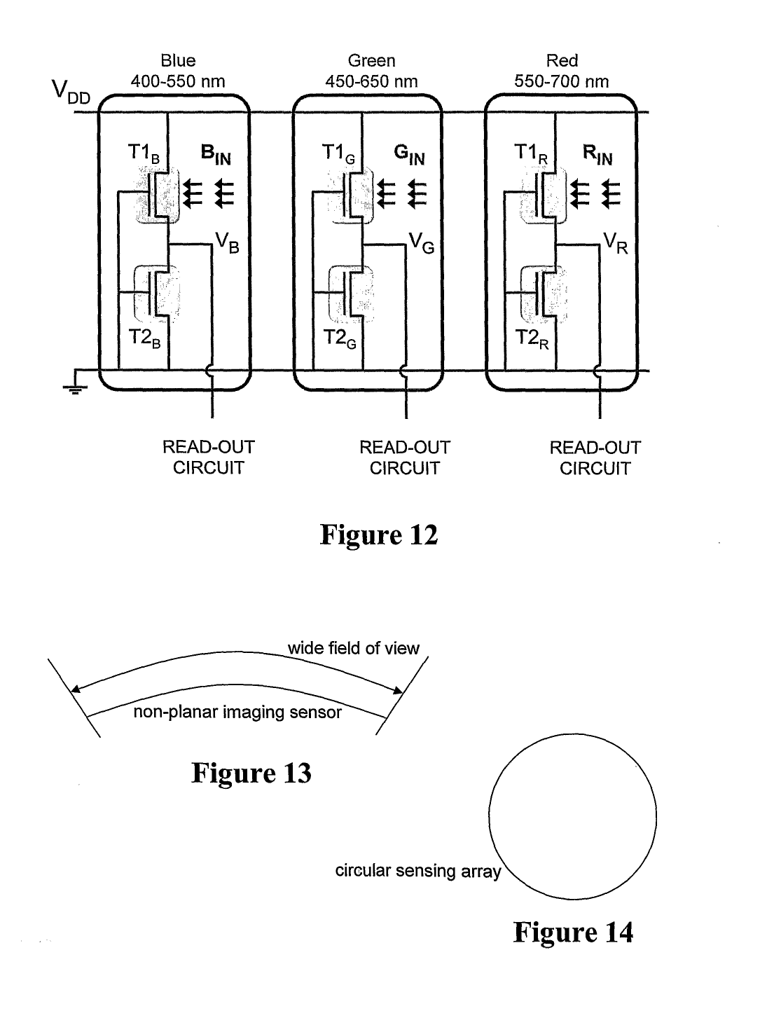

A simple full colour image sensor may be produced based on the optimised LS-OFETs described above. An example of the circuitry of a single RGB pixel is shown in FIG. 12. The single RGB pixel circuit employs three sub-pixels, each sub-pixel incorporating one wavelength-selective LS-OFET (i.e. T1_{B}, T1_{G} or T1_{R}) and one unipolar transistor (i.e. T2_{B}, T2_{G} or T2_{R}) as part of the driving circuitry. To achieve full-colour detection capabilities, each of the three LS-OFETs should exhibit different spectral responses that cover the entire visible electromagnetic spectrum. For example, T1_{B} may be designed to have a spectral response in the range of 400-550 nm (blue), T1_{G} in the 450-650 nm (green) and T1_{R} between 550-700 nm (red). Although initially this may be achieved using external colour filters, design of LS-OFETs having the desired spectral response may ultimately be achieved.

Using the colour sensing pixel of FIG. 12, the colour information of the light, incident on the surface of the array may be decomposed into red, green and blue colour primaries, determined by the spectral response of the three individual LS-OFETs. Processing of the three voltage outputs, i.e. V_{B}, V_{G}, Y_{R}, of each sub-pixel allows calculation of the CIE colour coordinates of the incident light. By integrating a large number of such RGB sensing pixels, each say 10 μm in size, fabrication of large-area image sensors is in principle possible. The spectral response of the LS-OFETs can also be adjusted to resemble the spectral response of the rods and cones in the human retina, enabling the construction of a retinomorphic imaging device with human visual characteristics. The integration of electronic circuitry also enables local signal processing in a manner performed by the human visual cortex.

The processing advantages of organic semiconductors combined with the fabrication simplicity of LS-OFETs based arrays provides a unique opportunity for fabricating low-cost, full-colour, small- as well as large-area image sensors suitable for a variety of applications. To date there has been no disclosure describing any such sensor arrays.

Possible applications for sensors using this technology include:
A colour imaging device or sensing array produced on a curved or flexible substrate, thereby forming a curved or flexible imaging device. For example, a camera may be formed having a non-planar imaging sensor, e.g. as shown in FIG. 13, in order to capture a wide field of view. Taken to an extreme, the imaging sensor may even curve through 360°, as illustrated in FIG. 14, thereby capturing the entire surroundings of the sensor. A spherical, hemispherical or dome-shaped imaging device may be produced in a similar manner. Similarly, imaging devices which operate like the retina of the human eye may be produced.
A wearable ultra-violet detector (e.g. incorporating an LED or LCD, or an electrophoretic display to provide the user with information as to the levels of incident UV radiation).
Medical imaging devices (small or large in area).
Infra-red detectors (e.g. for telecommunication and military applications).

Using LS-OFET sensors, integrated devices may readily be made, without the need to attach separate devices together, e.g. using pick & place assembly methods with associated location alignment and wiring issues.

LS-OFET based sensor arrays may be produced using existing manufacturing techniques that will be known to those skilled in the art.

Since light detected by LS-OFET based sensor arrays may be processed using analogue circuitry, this enables logic operations to be performed on images or spatial patterns of light. For example, using analogue processing, a single output signal may be obtained that is representative of a complete input pattern of light. An input pattern of light may be compared against a look-up table very quickly and with minimal processing. This may be used to verify the authenticity of an input image, for example in security applications. Light detected by the LS-OFET based sensor arrays may also be used to perform computations, and data from different pixels may be compared.

If the application is such that optical sensitivity is more important than switching speed, then we recommend, for currently available materials sets, the use of a blended ambipolar layer in the LS-OFET(s). However, if the application is such that switching speed is more important than optical sensitivity, then we recommend, for currently available materials sets, the use of a multilayer ambipolar structure in the LS-OFET(s).

### 4. Summary of Some of the Technical Advantages and Possible Applications of the Present Embodiments of LS-OFETs

### 4.1 Light Sensing Applications:

1. LS-OFETs exhibit lower RC constants and have the potential for faster operation, i.e. switching frequency. This is of particular interest for opto-electrical switches such as the ones used in telecom networks or in fast image capture/processing devices.

2. LS-OFETs can be integrated in light/colour sensing arrays as part of the driving electronics by employing the same technology without the need of any additional fabrication steps.

3. LS-OFETs can be realised using noble electrode materials such as Au without the need of the highly oxidization-sensitive metal electrodes (Ca, Al, etc) typically used in organic photodiodes. Therefore their environmental stability is expected to be much better. However, oxidising materials could be used if required.

### 4.2 Electro-Optical Circuits and Switches:

By using LS-OFETs, novel electro-optical switches and circuits may be fabricated.

### SUMMARY

The present embodiments demonstrate LS-OFETs with fast electro-optical switching characteristics for use, primarily, in optical sensing, optoelectronic integrated circuits and switches, although other applications are possible. Our currently-preferred approach is based on the use of ambipolar OFETs and the measurable photovoltaic effect present upon illumination of the device with light. The significant concentration of free carriers, generated upon photoexcitation, can modulate the current across the channel and hence transform the transistor to an electro-optical switch. Use of ambipolar OFETs has the potential to maximise the photovoltaic response of such devices, while use of appropriate organic semiconductor systems is expected to lead to LS-OFETs with wavelength-selective characteristics. Such devices are expected to become important in colour measurement and image sensing applications. High-performance LS-OFETs will also pave the way towards electro-optical circuits, in which signal processing involves the use of both optical and electrical signals. To date these ideas have not been given any significant consideration. We strongly believe that our work has the potential to reshape the landscape of plastic electronics.

### REFERENCES

[1] G. Gelinck et al. Nat. Mater. 3, 106 (2004).
[2] J. Zaumzeil et al. Nat. Mater. 5, 69 (2006).
[3] N. Marjanovic et al. Org. Elect. 7, 188 (2006).
[4] T. D Anthopoulos et al. Adv. Mater. 16, 2174 (2004).
[5] T. D Anthopoulos et al. Adv. Mater. 18, 1900 (2006).
[6] E. Smits, T. D. Anthopoulos et al. Adv. Mater. 19, 734 (2007).
[7] C. D. Dimitrakopoulos, P. R. L. Malenfant, Adv. Mater. 14, 99 (2002).
[8] S. Dutta and K. S. Narayan, Synth. Met. 146, 321 (2004).
[9] Y. Xu et al. Appl. Phys. Lett. 85, 4219 (2004).
[10] S. Cho et al. Appl. Phys. Lett. 90, 063511 (2007).
[11] Y. Kim, et al. Nat. Mater. 5, 197 (2006).
[12] P. Peumans et al. J. Appl. Phys. 93, 3693 (2003).
[13] J. C. Brabec et al. Adv. Fun. Mater. 11, 15 (2001); H. Hoppe et al. Adv. Fun. Mater. 14, 1005 (2004).
[14] Y. Sakamoto et al. J. Am. Chem. Soc. 126, 8138 (2004).
[15] J. Wang et al. Org. Elect. 1, 33 (2000).
[16] T. D Anthopoulos et al. Mater. Res. Symp. Proc. 871E, I11.9.1 (2005).

1. An organic field-effect transistor comprising:
a source region;
a drain region;
one or more organic semiconductor layers disposed between the source and drain regions;
a gate region; and
a dielectric region disposed between the organic semiconductor layer(s) and the gate region;
wherein the composition of the organic semiconductor layer(s) is such as to transport both electrons and holes, with the mobility of the holes being substantially equal to the mobility of the electrons such that the transistor substantially exhibits ambipolarity in its transfer characteristics.

2-61. (canceled)

62. A transistor as claimed in claim 1, wherein the said organic semiconductor layer(s) comprises a single layer.

63. A transistor as claimed in claim 62, wherein the organic semiconductor layer is a blend of n-type and p-type semiconductor materials.

64. A transistor as claimed in claim 63, wherein the n-type semiconductor material comprises fullerene.

65. A transistor as claimed in claim 64, wherein the fullerene comprises [60]PCBM.

66. A transistor as claimed in claim 64, wherein the fullerene is a perfluorinated fullerene derivative.

67. A transistor as claimed in claim 63, wherein the p-type semiconductor material comprises an organic polymer.

68. A transistor as claimed in claim 67, wherein the organic polymer comprises OC₁C₁₀-PPV.

69. A transistor as claimed in claim 67, wherein the organic polymer comprises a polythiophene derivative such as P3HT.

70. A transistor as claimed in claim 63, wherein the n-type semiconductor material comprises [60]PCBM and the p-type semiconductor material comprises OC₁C₁₀-PPV.

71. A transistor as claimed in claim 70, wherein the [60]PCBM:OC₁C₁₀-PPV ratio is in the range of approximately 8:1 to 20:1 by weight.

72. A transistor as claimed in claim 71, wherein the [60]PCBM:OC₁C₁₀-PPV ratio is in the range of approximately 15:1 to 20:1 by weight.

73. A transistor as claimed in claim 62, wherein the organic semiconductor layer is adapted such that free carrier photogeneration and transport occurs within the semiconductor layer.

74. A transistor as claimed in claim 73, wherein the semiconductor layer comprises dithiolene or squaraine or derivatives thereof.

75. A transistor as claimed in claim 73, wherein the organic semiconductor layer comprises a single molecular species.

76. A transistor as claimed in claim 62, wherein the organic semiconductor layer is a single material.

77. A transistor as claimed in claim 1, wherein the said organic semiconductor layer(s) comprise first and second organic semiconductor layers.

78. A transistor as claimed in claim 77, wherein the said first and second organic semiconductor layers comprise separate n-channel and p-channel layers.

79. A transistor as claimed in claim 78, further comprising a third layer between the first and second organic semiconductor layers, the third layer being a high photogeneration efficiency layer.

80. A transistor as claimed in claim 1, wherein the channel length from the source region to the drain region is in the range of approximately 0.5 μm to 50 μm.

81. A transistor as claimed in claim 80, wherein the channel length from the source region to the drain region is in the range of approximately 1 μm to 2 μm.

82. A transistor as claimed in claim 1, fabricated on a flexible substrate.

83. A transistor as claimed in claim 1, fabricated on a non-planar substrate.

84. A transistor as claimed in claim 1, being a light-sensing organic field-effect transistor.

85. An electro-optical switch comprising a light-sensing organic field-effect transistor as claimed in claim 84.

86. An electro-optical switch as claimed in claim 85, having a switching speed of the order of kHz or faster.

87. An organic field-effect transistor comprising:
a source region;
a drain region;
one or more organic semiconductor layers disposed between the source and drain regions;
a gate region; and
a dielectric region disposed between the organic semiconductor layer(s) and the gate region;
wherein the channel length from the source region to the drain region is in the range of approximately 0.5 μm to 50 μm.

88. A transistor as claimed in claim 87, wherein the channel length from the source region to the drain region is in the range of approximately 1 μm to 2 μm.

89. An organic field-effect transistor comprising:
a source region;
a drain region;
first and second organic semiconductor layers disposed between the source and drain regions;
a gate region; and
a dielectric region disposed between the gate region and the first and second organic semiconductor layers;
wherein the said first and second organic semiconductor layers comprise separate n-channel and p-channel layers.

90. A transistor as claimed in claim 89, further comprising a third layer between the first and second organic semiconductor layers, the third layer being a high photogeneration efficiency layer.

91. An organic field-effect transistor comprising:
a source region;
a drain region;
an organic semiconductor layer disposed between the source and drain regions, the organic semiconductor layer being a unipolar transport layer;
a photosensitizer layer disposed on the unipolar transport layer;
a gate region; and
a dielectric region disposed between the gate region and the organic semiconductor layers.

92. A method of forming an organic field-effect transistor comprising:
forming a dielectric layer on a gate;
forming a source region and a drain region; and
depositing one or more organic semiconductor layer(s) on the dielectric layer;
wherein the composition of the organic semiconductor layer(s) is such as to transport both electrons and holes, with the mobility of the holes being substantially equal to the mobility of the electrons such that the transistor substantially exhibits ambipolarity in its transfer characteristics.

93. A method of forming an organic field-effect transistor comprising:
forming a dielectric layer on a gate;
forming a source region and a drain region; and
depositing one or more organic semiconductor layer(s) on the dielectric layer, wherein the channel length from the source region to the drain region is in the range of approximately 0.5 μm to 50 μm.

94. A method of forming an organic field-effect transistor comprising:
forming a dielectric layer on a gate;
forming a source region and a drain region; and
depositing first and second organic semiconductor layers on the dielectric layer;
wherein the said first and second organic semiconductor layers comprise separate n-channel and p-channel layers.

95. A method of forming an organic field-effect transistor comprising:
forming a dielectric layer on a gate;
forming a source region and a drain region;
depositing an organic semiconductor layer on the dielectric layer, the organic semiconductor layer being a unipolar transport layer; and
depositing a photosensitizer layer on the unipolar transport layer.

96. A method of forming an organic field-effect transistor comprising:
forming a dielectric layer on a gate;
forming a source region and a drain region; and
depositing a single ambipolar organic semiconductor layer on the dielectric layer, the single ambipolar organic semiconductor layer being adapted such that free carrier photogeneration and transport occurs within the semiconductor material.

97. An electro-optical circuit comprising a light-sensing organic field-effect transistor.

98. An image sensing array comprising a plurality of light-sensing organic field-effect transistors.
